(19) United States
(12) Patent Application Publication
(10) Pub. No.: US 2010/0283084 A1
(43) Pub. Date: Nov. 11, 2010

(54) BIPOLAR TRANSISTOR AND METHOD FOR FABRICATING THE SAME

(76) Inventors: Teruhito Ohnishi, Toyama (JP); Ken Idota, Toyama (JP); Atsushi Nakamura, Hyogo (JP)

Correspondence Address: MCDERMOTT WILL & EMERY LLP, 600 13TH STREET, NW, WASHINGTON, DC, 20005-3096, US

(21) Appl. No.: 12/730,878

(22) Filed: Mar. 24, 2010

(30) Foreign Application Priority Data
May 8, 2009 (JP) 2009-113489

(51) Int. Cl. H01L 29/737; H01L 21/331

(52) U.S. Cl. 257/197; 438/312; 257/E29.188; 257/E21.371

(57) ABSTRACT

The bipolar transistor includes a heterojunction intrinsic base layer epitaxially grown on a collector layer. The intrinsic base layer is disposed on the collector layer surrounded by an isolation layer, and an N-type impurity layer is formed in a surface portion of the collector layer. The impurity concentration of the N-type impurity layer is higher than the impurity concentration of the collector layer under the N-type impurity layer. Between the N-type impurity layer and the intrinsic base layer, an epitaxially grown layer is formed, where the epitaxially grown layer is lower in impurity concentration than the N-type impurity layer and the intrinsic base layer.

### CROSS-REFERENCE TO RELATED APPLICATION

This application claims priority to Japanese Patent Application No. 2009-113489 filed on May 8, 2009, the disclosure of which including the specification, the drawings, and the claims is hereby incorporated by reference in its entirety.

### BACKGROUND

Heterojunction bipolar transistors (hereinafter sometimes referred to as HBTs) have superior, high-speed, and high-current drivability, and thus have been utilized as communication devices for, for example, mobile communications which require high-speed operation and high integration.

In recent years in particular, bipolar transistors are formed to have a heterojunction structure such as Si/SiGe, Si/SiGeC, or the like to provide heterojunction bipolar transistors having a cutoff frequency of higher than 100 GHz.

An example of methods for fabricating such HBTs is described in Japanese Patent Publication No. H11-354537. The method is characterized by implantation performed in a self-aligned manner to provide a device having increased high-frequency performance.

Meanwhile, amplifiers for wireless transmission for mobile phones, wireless LANs, and the like require high power, and thus for such amplifiers for wireless transmission, HBTs using a compound such as GaAs which is superior in breakdown voltage to silicon-based HBTs have been used.

In recent years, as the cost and size of wireless components mounted on mobile devices are reduced, attentions have been given to amplifiers for transmission using SiGe-HBTs (i.e., HBTs having a Si/SiGe heterojunction structure). Note that in order to use such a SiGe-HBT as an amplifier for transmission, it is preferable to improve the breakdown voltage, to reduce the leak current, and to increase the amplification factor of the SiGe-HBT. Here, in order to improve the breakdown voltage of the SiGe-HBT, it is known to reduce the concentration of a collector, and to increase the thickness of the collector.

### SUMMARY

However, reducing the collector concentration in order to improve the breakdown voltage of a bipolar transistor having a heterojunction as the above-described SiGe-HBT may reduce its transistor performance. In particular, this problem becomes significant during operation with a high base voltage. When a collector current is reduced, a current amplification factor hFE, a cutoff frequency fT, and the like rapidly decrease (in comparison to the case where the collector concentration is not reduced).

In view of the above-discussed problems, a heterojunction bipolar transistor whose transistor performance is less susceptible to degradation while its breakdown voltage is improved, and a method for fabricating the same will be described below.

The inventors of the present application studied causes degrading the transistor performance when the collector concentration is reduced. In the cause of the study, the inventors observed that when the collector concentration is reduced to improve the breakdown voltage, a parasitic barrier is formed at the base-collector junction (at the heterojunction) during the operation with a high base voltage. When such a parasitic barrier is formed, a depressed region is formed in the conduction band, thereby increasing the electron concentration in this region, so that recombination with holes tends to occur. As a result, a base current increases, which causes, for example, a rapid decrease in hFE.

Thus, the inventors of the present application came up with the idea of lowering the parasitic barrier to alleviate increase in electron concentration. Specifically, a bipolar transistor according to the present disclosure includes: a heterojunction intrinsic base layer epitaxially formed on a collector layer, wherein the intrinsic base layer is disposed on the collector layer surrounded by an isolation layer, an N-type impurity layer is formed in a surface portion of the collector layer, where an impurity concentration of the N-type impurity layer is higher than an impurity concentration of the collector layer under the N-type impurity layer, and between the N-type impurity layer and the intrinsic base layer, an epitaxially grown layer is formed, where the epitaxially grown layer is lower in impurity concentration than the N-type impurity layer and the intrinsic base layer.

Note that it is preferable that an emitter layer is provided on the intrinsic base layer, and an emitter electrode made of polysilicon is provided on the emitter layer.

Since such a bipolar transistor includes an N-type impurity layer, a region in which band energy is reduced is formed in the N-type impurity layer. For this reason, even if a parasitic barrier is formed in the vicinity of the base-collector junction due to a high base voltage, energy in the vicinity of the base-collector junction is reduced under the influence of the region in which the band energy is reduced. That is, in comparison to the case where the N-type impurity layer is not provided, the parasitic barrier is lowered in the case where the

N-type impurity layer is provided. As a result, the increase in electron concentration in the conduction band is alleviated, thereby reducing the recombination with holes, so that it is possible to alleviate the increase in base current. Thus, in the case where the collector concentration is reduced to improve the breakdown voltage, the transistor performance can be less susceptible to degradation.

Here, the intrinsic base layer is a base layer under or in the vicinity of the emitter layer, and is a base determining the transistor performance.

Moreover, the intrinsic base layer is preferably made of a mixed-crystal material containing at least Si and Ge. A specific example the intrinsic base layer may have such a configuration.

Moreover, the epitaxially grown layer preferably has a thickness of greater than or equal to 5 nm and less than or equal to 100 nm. More preferably, the epitaxially grown layer has a thickness of greater than or equal to 10 nm and less than or equal to 80 nm.

The epitaxially grown layer needs to have a certain thickness in order to be able to compensate crystal defects on the collector layer to form a high-quality film, and preferably has a thickness of 5 nm or larger, and more preferably 10 nm or larger. On the other hand, the larger the thickness of the epitaxially grown layer is, the longer transit time electrons need, thereby degrading the transistor performance (cutoff frequency fT and the like). Therefore, the thickness of the epitaxially grown layer is preferably 100 nm or less, and more preferably 80 nm or less.

Moreover, the epitaxially grown layer is preferably an undoped silicon layer.

Moreover, the N-type impurity layer is preferably formed by ion implantation.

Moreover, the intrinsic base layer is preferably made of a mixed-crystal material containing at least Si, Ge, and C.

Specific examples of these layers may have such configurations respectively.

Next, to achieve the above object, a method for fabricating a bipolar transistor according to the present disclosure includes: (a) forming a single-crystal silicon layer on a collector layer provided on a silicon substrate; (b) forming in the single-crystal silicon layer, a collector lead layer and an N-type impurity layer which are isolated from each other by an isolation layer, where the N-type impurity layer is higher in impurity concentration than the collector lead layer; (c) forming an epitaxially grown layer on the N-type impurity layer, and forming an intrinsic base layer on the epitaxially grown layer; (d) forming an emitter electrode over the intrinsic base layer with an oxide film interposed therebetween; and (e) forming an emitter layer in an upper portion of the intrinsic base layer by dispersing impurities from the emitter electrode to the intrinsic base layer by a thermal treatment.

With these processes, it is possible to fabricate the bipolar transistor according to the present disclosure. Moreover, forming the epitaxially grown layer at (c) can compensate crystal defects on the N-type impurity layer to increase the quality of the intrinsic base layer.

Note that a layered structure including the epitaxially grown layer and the intrinsic base layer formed at (c) preferably includes a layer made of Si, a layer made of a mixed-crystal material of Si and Ge, and a layer made of a mixed-crystal material of Si and Ge and having a concentration gradient. A specific example of the layered structure may have such a configuration.

As described above, according to the configuration of the bipolar transistor of the present disclosure, energy is reduced in a region in which the N-type impurity layer is provided. Therefore, when a parasitic barrier is about to be formed at the time of increasing the base potential, the fact that the energy is reduced in the region provided with the N-type impurity layer exerts the influence of reducing the formation of the parasitic barrier. Thus, in the heterojunction bipolar transistor, the transistor performance can be less susceptible to degradation while the breakdown voltage is improved.

### BRIEF DESCRIPTION OF THE DRAWINGS

FIGS. 1A and 1B are views illustrating cross-sectional structures of an example intrinsic bipolar transistor of an embodiment of the present disclosure.

FIG. 2 is a cross-sectional view illustrating a process in a method for fabricating the example intrinsic bipolar transistor of the embodiment.

FIG. 3 is a cross-sectional view illustrating a process in the method for fabricating the example intrinsic bipolar transistor of the embodiment.

FIG. 4 is a cross-sectional view illustrating a process in the method for fabricating the example intrinsic bipolar transistor of the embodiment.

FIG. 5 is a cross-sectional view illustrating a process in the method for fabricating the example intrinsic bipolar transistor of the embodiment.

FIG. 6 is a cross-sectional view illustrating a process in the method for fabricating the example intrinsic bipolar transistor of the embodiment.

FIG. 7 is a cross-sectional view illustrating a process in the method for fabricating the example intrinsic bipolar transistor of the embodiment.

FIG. 8 is a cross-sectional view illustrating a process in the method for fabricating the example intrinsic bipolar transistor of the embodiment.

FIG. 9 is a cross-sectional view illustrating a process in the method for fabricating the example intrinsic bipolar transistor of the embodiment.

FIG. 10 is a cross-sectional view illustrating a process in the method for fabricating the example intrinsic bipolar transistor of the embodiment.

FIG. 11 is a cross-sectional view illustrating a process in the method for fabricating the example intrinsic bipolar transistor of the embodiment.

FIG. 12 is a cross-sectional view illustrating a process in the method for fabricating the example intrinsic bipolar transistor of the embodiment.

FIG. 13 is a view illustrating the hFE linearity characteristics of an example SiGe-HBT and a SiGe-HBT of a comparative example.

FIG. 14 is a view illustrating the band energy of the example SiGe-HBT.

FIG. 15 is a view illustrating the band energy of the SiGe-HBT of the comparative example.

FIGS. 16A and 16B are views illustrating high-frequency performance (fT and fmax) of the example transistor and the transistor of the comparative example.

### DETAILED DESCRIPTION

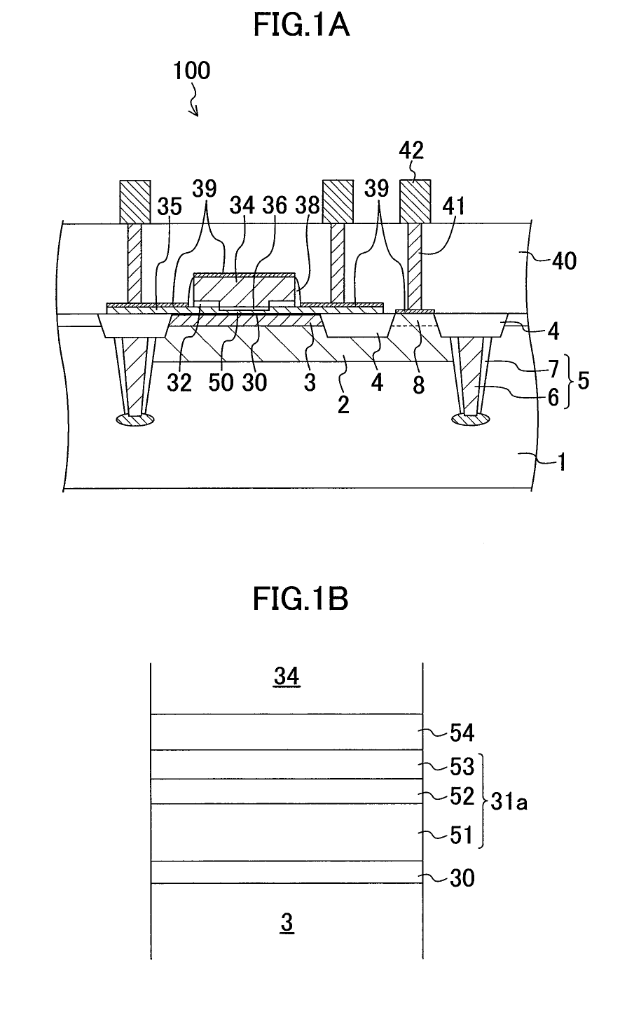

An intrinsic bipolar transistor of an embodiment of the present disclosure and a method for fabricating the same will be described below with reference to the drawings. FIG. 1A is a view schematically illustrating a cross section of a major part of an example bipolar transistor 100. FIG. 1B is an enlarged view illustrating a layered structure in the vicinity of the base of the bipolar transistor 100.

As shown in FIG. 1A, the bipolar transistor 100 is formed using a P-type silicon substrate 1 whose principal plane is the (001) plane. In an upper portion of the P-type silicon substrate 1, an N-type sub-collector 2 containing arsenic (As) is formed. The N-type sub-collector 2 is surrounded by a deep trench 5 reaching the P-type silicon substrate 1 and a shallow trench 4 provided on the deep trench 5. A surface of the N-type sub-collector 2 is further divided by a shallow trench 4. Here, the deep trench 5 includes an undoped polysilicon film 6 filling a groove reaching the P-type silicon substrate 1, and a silicon oxide film 7 surrounding the undoped polysilicon film 6. Moreover, the shallow trenches 4 each have a configuration in which a groove shallower than the N-type sub-collector 2 is filled with a silicon oxide film.

In a surface portion of the N-type sub-collector 2 divided by the shallow trench 4, a single-crystal Si layer 3 doped with N-type impurities is formed. Moreover, in a surface portion of the single-crystal Si layer 3, an N-type impurity layer is provided. The N-type impurity layer will be hereinafter referred to as a band modulation layer 30. The band modulation layer 30 includes N-type impurities at a higher concentration than the single-crystal Si layer 3 directly under the band modulation layer 30. The N-type sub-collector 2, the single-crystal Si layer 3, and the band modulation layer 30 constitute the collector of the bipolar transistor 100.

Moreover, in the other part of the surface portion of the N-type sub-collector 2 divided by the shallow trench 4, an N⁺-type collector lead layer 8 is formed. The N⁺-type collector lead layer 8 is a single-crystal Si layer including N-type impurities at a higher concentration than the N-type sub-collector 2.

An emitter polysilicon electrode 34 is formed on an emitter layer 36 on a base layer 50 on the band modulation layer 30. Around the base layer 50, an extrinsic base electrode 35 extends over the shallow trench 4. Moreover, around the emitter layer 36, an oxide film 32 is provided between the extrinsic base electrode 35 and the emitter polysilicon electrode 34. On side surfaces of the emitter polysilicon electrode 34, sidewalls 38 are provided. On upper surfaces of the extrinsic base electrode 35 and the emitter polysilicon electrode 34, a Co silicide layer 39 is provided.

Over the P-type silicon substrate 1, an interlayer dielectric layer 40 is formed to cover the emitter polysilicon electrode 34, the extrinsic base electrode 35, and the like. Tungsten plugs 41 are formed through the interlayer dielectric layer 40 to be electrically connected to the extrinsic base electrode 35 and to the N⁺-type collector lead layer 8. On the interlayer dielectric layer 40, metal interconnects 42 containing aluminum are provided to be connect to the tungsten plugs 41. Although not shown in the figure, a plug electrically connected to the emitter polysilicon electrode 34 is also provided.

FIG. 1B illustrates a further detailed layered structure in the vicinity of the emitter layer 36. As shown in FIG. 1B, a SiGe layered film 31a including a plurality of epitaxially grown layers is formed to cover the band modulation layer 30 provided on the single-crystal Si layer 3. Specifically, the SiGe layered film 31a includes a Si buffer layer 51 having a thickness of about 60 nm and formed on the band modulation layer 30, a SiGe layer 52 formed on the Si buffer layer 51, and a SiGe concentration gradient layer 53 formed on the SiGe layer 52. Note that for the sake of simplicity, the notation “SiGe” is used, but this does not mean that the composition of Si and Ge is 1:1. These layers each have composition expressed by Si₁₋ₓGeₓ (0<x≦1).

On the SiGe layered film 31a, a Si cap layer 54 made of silicon (not shown in FIG. 1A) is formed. On the Si cap layer 54, the emitter polysilicon electrode 34 is provided.

Here, the SiGe concentration gradient layer 53 forms a base layer whose graded composition is such that the concentration of Ge decreases toward the emitter polysilicon electrode 34. The emitter layer 36 is formed by dispersing impurities (e.g., phosphorus) from the emitter polysilicon electrode 34 to the Si cap layer 54, which will be further described later.

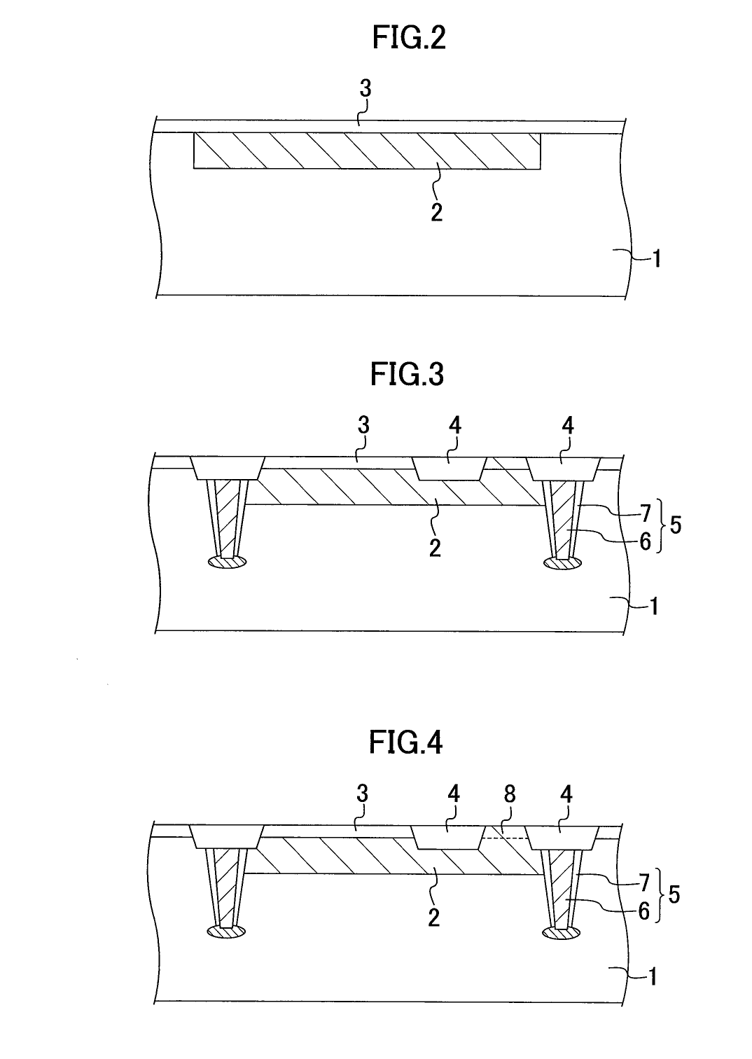

Next, a method for fabricating the bipolar transistor 100 will be described with reference to FIGS. 2-12 which are cross-sectional views schematically illustrating processes in the method.

First, as shown in FIG. 2, in a predetermined region (HBT formation region) in an upper portion of a P-type silicon substrate 1 whose principal plane is the (001) plane, an N-type sub-collector 2 having a depth of about 1 μm is formed. For this purpose, a resist having an opening in a region in which the N-type sub-collector 2 is to be formed may be formed on the P-type silicon substrate 1 by photolithography, and by using the resist as a mask, arsenic (As) ions may be implanted.

Next, on the P-type silicon substrate 1 including over the N-type sub-collector 2, a single-crystal Si layer 3 is epitaxially grown to have a thickness of about 0.85 μm while being doped with N-type impurities. Here, the concentration of the impurities is about 1×10¹⁵ atoms/cm³.

Next, as shown in FIG. 3, device isolation is formed. Specifically, a shallow trench 4 and a deep trench 5 under the shallow trench 4 are formed to surround the N-type sub-collector 2. The shallow trench 4 is filled with a silicon oxide film. The deep trench 5 includes an undoped polysilicon film 6 and a silicon oxide film 7 surrounding the undoped polysilicon film 6. Moreover, in the region surrounded by the shallow trench 4 and the deep trench 5, only a shallow trench 4 is formed for sectionalization. Note that the shallow trenches 4 each have a depth of about 0.3 μm, and the deep trench 5 has a depth of about 2 μm. Moreover, boron is implanted to a bottom of the deep trench 5 to prevent punch-through.

Next, as shown in FIG. 4, an N⁺-type collector lead layer 8 is formed. For this purpose, a resist (not shown) having an opening over a predetermined region surrounded by the shallow trench 4 is used as a mask to implant phosphorus (P) ions into the single-crystal Si layer 3. This process is carried out, for example, at an implantation energy of about 60 keV, and a dose amount of 3×10¹⁵ atoms/cm². After that, the resist is removed by oxygen plasma ashing. Further, a thermal treatment is performed at a temperature of about 850° C. for about 30 minutes to obtain the N⁺-type collector lead layer 8.

Next, by photolithography and ion implantation, arsenic is implanted into the N⁺-type collector lead layer 8 at an implantation energy of about 50 keV, and a dose amount of 3×10¹⁵ atoms/cm².

Next, as shown in FIG. 5, an oxide film 28 having a thickness of about 50 nm is deposited by low pressure CVD to cover the P-type silicon substrate 1. Further, on the oxide film 28, a polysilicon film 29 having a thickness of about 100 nm is deposited by low pressure CVD.

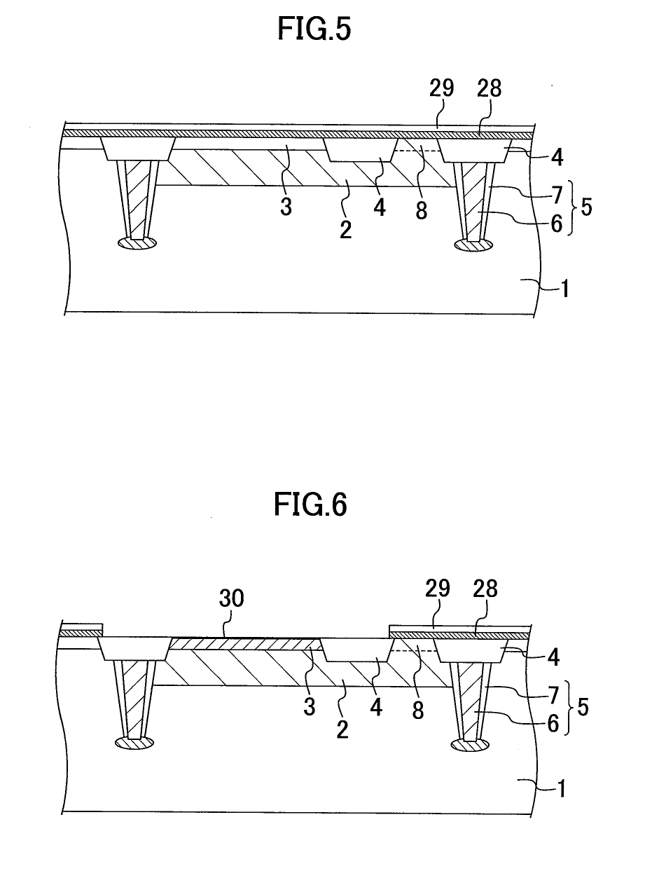

Next, as shown in FIG. 6, in an upper portion of the single-crystal Si layer 3 surrounded by the shallow trench 4, a band modulation layer 30 serving as an N-type impurity layer is formed. For this purpose, first, a resist (not shown) having an opening in the HBT formation region is formed by photolithography, and by using the resist as a mask, the polysilicon film 29 is removed (although FIG. 6 illustrates a configuration in which the oxide film 28 is also removed, the oxide film 28 remains at this point without being removed). Then, phosphorus is implanted at an implantation energy of 50 keV, and a dose amount of about 2×10¹¹ atoms/cm².

Thus, in the single-crystal Si layer 3, the band modulation layer 30 containing phosphorus is formed as an N-type impurity layer. When the implantation energy is 50 keV, a band modulation layer 30 having a depth (width) of about 0.08 μm is formed. Note that since it is known that the breakdown voltage decreases when the dose amount is larger than 2×10¹² atoms/cm², the dose amount is set to 2×10¹² atoms/cm² or less. Moreover, the band modulation layer 30 has a depth of 0.08 μm, but this is a mere example. It is confirmed that a band modulation layer having a depth of up to about 0.3 μm can be used as a transistor.

Next, the resist is removed by oxygen plasma ashing, and then a thermal treatment at a temperature of about 1000° C. for 10 seconds is performed in order to activate the heretofore implanted impurities, to compensate crystal defects, and the like.

After that, the oxide film 28 exposed in a region from which the polysilicon film 29 has been removed is removed by hydrofluoric acid to expose a surface of the N-type Si in the HBT formation region. Due to the removal of the oxide film 28, the silicon oxide film in the shallow trench 4 is also etched away, so that part of the silicon substrate in which phosphorus is not implanted appears. However, the part is away from the region in which the intrinsic transistor is to be formed, so that this does not affect the transistor performance.

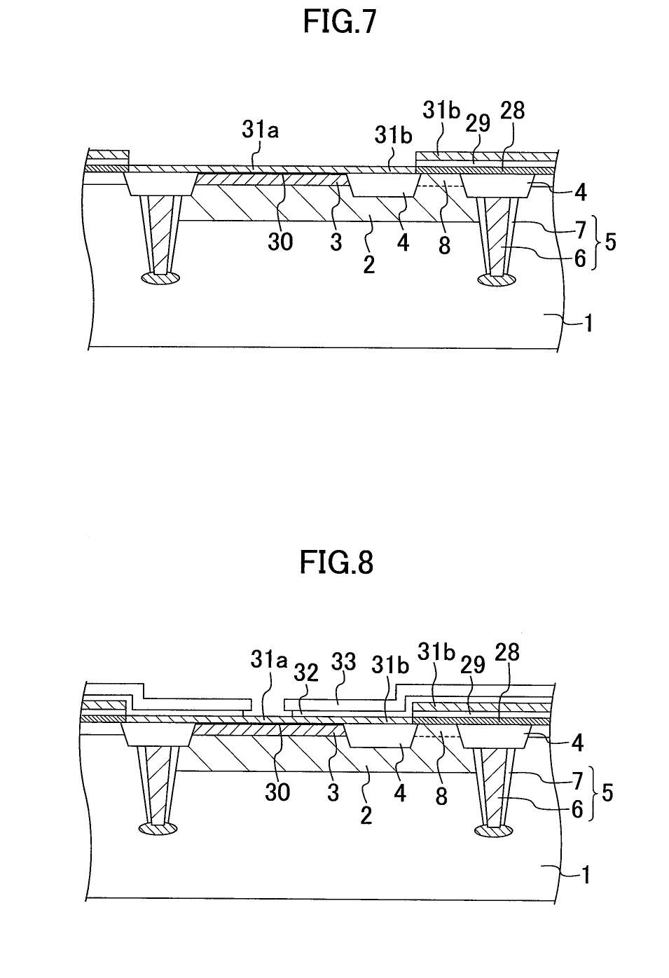

Next, as shown in FIG. 7, an epitaxially grown SiGe layered film 31a and a poly-SiGe layered film 31b are simultaneously deposited respectively on the band modulation layer 30 and on the shallow trench 4 and the polysilicon film 29 by ultra-high vacuum chemical vapor deposition (UHV-CVD).

The SiGe layered film 31a has the structure illustrated in FIG. 1B. That is, the structure includes a Si buffer layer 51 having a thickness of about 60 nm, a SiGe layer 52 having a thickness of about 20 nm and formed on the Si buffer layer 51, and a SiGe concentration gradient layer 53 having a thickness of about 20 nm and formed on the SiGe layer 52, where the Si buffer layer 51, the SiGe layer 52, and the SiGe concentration gradient layer 53 are epitaxially grown layers.

The SiGe layer 52 has a concentration of Ge of about 30% (when the composition is expressed by Si₁₋ₓGeₓ, x=0.3 approximately). The SiGe concentration gradient layer 53 has such a graded composition that the concentration of Ge is about 30% in a portion close to the SiGe layer 52 from which the concentration of Ge lowers toward the emitter. Moreover, the SiGe concentration gradient layer 53 is a layer serving as a base layer, and is P-type due to about 3×10¹⁹ atoms/cm³ of boron (B) introduced during its film growth.

On the SiGe concentration gradient layer 53, a Si cap layer 54 having a thickness of about 35 nm is formed (FIG. 1B).

Moreover, the Si buffer layer 51 having a thickness of about 60 nm which is first epitaxially grown is provided close to the collector, thereby compensating crystal defects, probably caused by implantation, on a collector surface (surface portion serving as the band modulation layer 30 of the P-type silicon substrate 1), so that a high-quality silicon layer can be formed. When the Si buffer layer 51 is grown, a gas serving as an impurity is not used. Therefore, in the SiGe-HBT structure, the Si buffer layer 51 is provided between the band modulation layer 30 and the base layer 50 (FIG. 1B).

Moreover, the SiGe layered film 31b on the shallow trench 4 and on the polysilicon film 29 is formed as a film having a structure in which a poly Si₁₋ₓGeₓ film is stacked on a polysilicon film.

Next, the process illustrated in FIG. 8 is performed. First, an oxide film 32 having a thickness of about 30 nm, and a polysilicon film 33 having a thickness of about 50 nm and containing about 3×10¹⁵ atoms/cm³ of phosphorus are deposited by low pressure CVD. Next, a resist (not shown) having an opening in a region corresponding to an emitter region of the HBT is formed by photolithography. By using the resist as a mask, an opening is formed in the polysilicon film 33 by a dry etching technique. Then, the resist is removed.

Subsequently, part of the oxide film 32 which is exposed in the opening in the polysilicon film 33 is removed by wet etching.

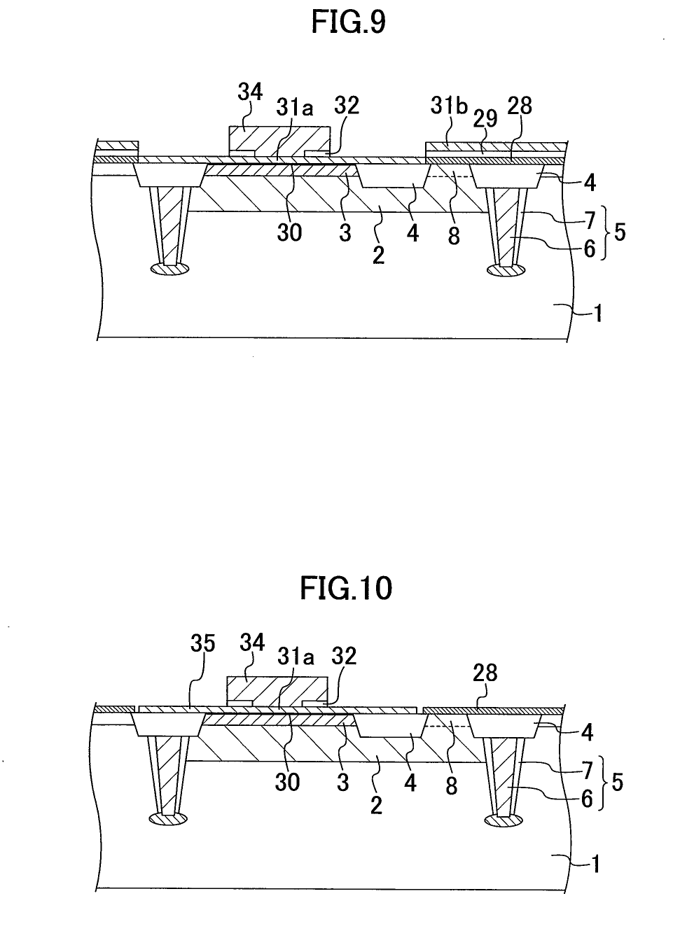

Next, as shown in FIG. 9, an emitter polysilicon electrode 34 made of a polysilicon film is formed on the SiGe layered film 31a. For this purpose, first, an N⁺-type amorphous silicon film having a thickness of about 300 nm and a concentration of about 5×10²⁰ atoms/cm³ is formed. For example, deposition at a temperature of about 540° C. may be performed by low pressure CVD. The amorphous silicon is subjected to a thermal treatment to form the polysilicon film constituting the emitter polysilicon electrode 34.

Subsequently, a resist (not shown) having an opening in a predetermined region is formed by photolithography. By using the resist as a mask, the polysilicon film is anisotropically etched to form the emitter polysilicon electrode 34. At this point, the polysilicon film 33 is also removed. Further, the oxide film 32 is removed by wet etching except part of the oxide film 32 which is located under the emitter polysilicon electrode 34. The configuration illustrated in FIG. 9 is thus obtained.

Next, as shown in FIG. 10, the SiGe layered film 31b is patterned by etching, thereby forming an extrinsic base electrode 35 of the HBT. For this purpose, a resist having an opening in a predetermined region may be formed by photolithography, and by using the resist as a mask, the etching may be performed. During the etching, the SiGe layered film 31b and the polysilicon film 29 over the N⁺-type collector lead layer 8, and the like are also removed.

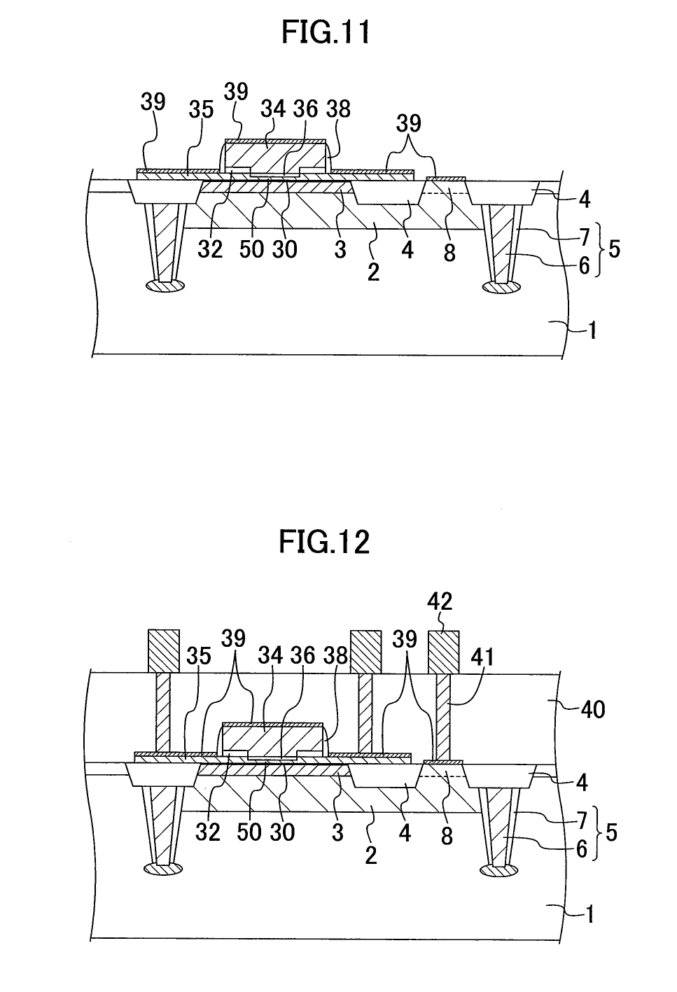

Next, as shown in FIG. 11, an emitter layer 36 under the emitter polysilicon electrode 34; sidewalls 38 covering side surfaces of the emitter polysilicon electrode 34; and a Co silicide layer 39 covering upper surfaces of the emitter polysilicon electrode 34, the extrinsic base electrode 35, and the N⁺-type collector lead layer 8 are formed.

For this purpose, first, an oxide film (not shown) having a thickness of about 30-100 nm is deposited by low pressure CVD. Next, a thermal treatment is performed at a temperature of about 900° C. for about 10-15 seconds to disperse impurities from the emitter polysilicon electrode 34 to the SiGe layered film 31a under the emitter polysilicon electrode 34, thereby forming the emitter layer 36.

In the present embodiment, the emitter polysilicon electrode 34 has a phosphorus concentration of 5×10^{°}atoms/cm³. However, the concentration of the emitter polysilicon electrode 34 can be accordingly changed to an optimal phosphorus concentration according to the thickness of the base layer, the concentration of the collector surface, and the like.

Moreover, part of the SiGe layered film 31a provided between the emitter layer 36 formed in this way and the band modulation layer 30 is the base layer 50.

Subsequently, the first formed oxide film having a thickness of about 30-100 nm is anisotropically etched to form the sidewalls 38 on the side surfaces of the emitter polysilicon electrode 34. At this time, the oxide film 28 is also removed. Thus, a silicon surface is exposed in a surface of the emitter polysilicon electrode 34, a surface of the extrinsic base electrode 35, and a surface of the N⁺-type collector lead layer 8.

Next, sputtering with Co and annealing are performed, and then unreacted Co is removed, and annealing is further performed to form the Co silicide layer 39 covering the exposed silicon surface.

After that, as shown in FIG. 12, a standard multilevel interconnection process is performed.

That is, an interlayer dielectric layer 40 is deposited to cover the P-type silicon substrate 1, and then connection holes are formed, where the connection holes pass through the interlayer dielectric layer 40, and reach the Co silicide layer 39 on the emitter polysilicon electrode 34, the extrinsic base electrode 35, and the N⁺-type collector lead layer 8. Subsequently, the connection holes are filled with a tungsten (W) film to form tungsten plugs 41 (W plugs). After that, an aluminum alloy film is sputtered and patterned by using a resist having an opening in a predetermined region as a mask. Thus, metal interconnects 42 connected to the tungsten plugs 41 and extending over the interlayer dielectric layer 40 are formed.

The bipolar transistor 100 of the present embodiment is thus formed.

The bipolar transistor 100 serving as a SiGe-HBT having the above-described structure includes the band modulation layer 30 under the intrinsic base layer, so that the transistor performance can be less susceptible to degradation while the breakdown voltage is improved. This will be described below. Note that the intrinsic base layer is a base layer under or in the vicinity of the emitter layer 36, and is a base determining the transistor performance.

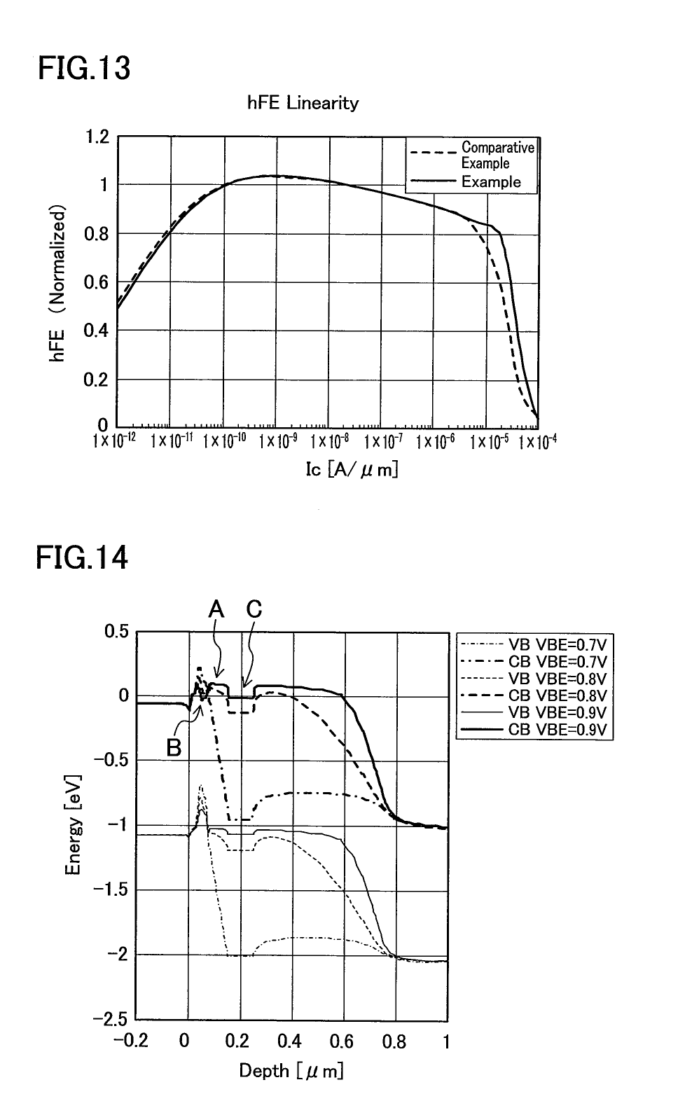

The dependence of the hFE on the collector current in the bipolar transistor 100 of the present embodiment is illustrated as an example in FIG. 13. Furthermore, as a comparative example, the dependence of the hFE on the collector current in a configuration of the bipolar transistor 100 of the present embodiment which does not include the band modulation layer 30 is illustrated in FIG. 13. Here, for the sake of simplicity of comparison, the dependence is illustrated in a normalized manner with the hFE with respect to a collector current Ic of 2×10⁻⁸ A/μm.

As shown in FIG. 13, in comparison to the bipolar transistor of the comparative example, the example bipolar transistor has a broader region in which the hFE variation with respect to the collector current Ic is small. In other words, the range of the collector current Ic in which the hFE variation is small is broader in the example bipolar transistor than in the bipolar transistor of the comparative example.

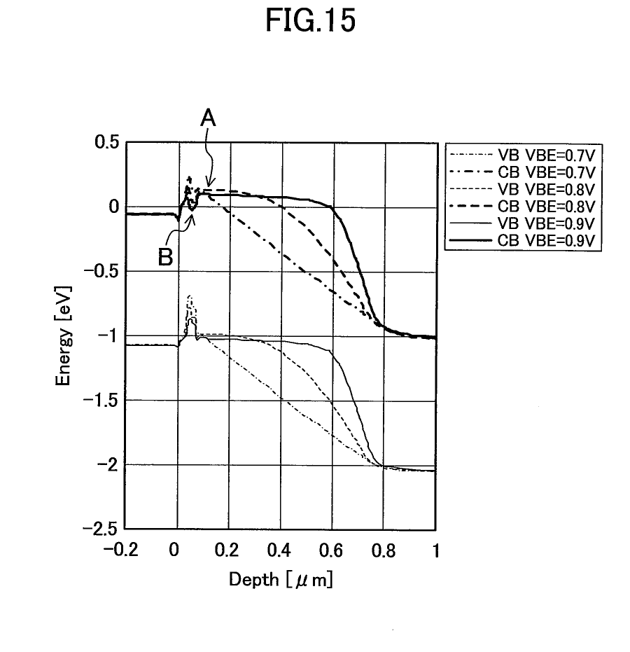

The reason for this can be explained with reference to FIGS. 14 and 15.

FIG. 14 illustrates band energy in a depth direction from the emitter to the collector of the example bipolar transistor 100, where the base potential (VBE) is used as a parameter. Specifically, the energy of the conduction band (CB) and the valence band (VB) is illustrated with respect to VBEs of 0.7 V, 0.8 V, and 0.9 V. Moreover, FIG. 15 likewise illustrates band energy of the bipolar transistor of the comparative example which does not include the band modulation layer 30. Note that the location where the depth is 0 μm corresponds to an upper surface of the emitter layer 36.

In a heterojunction, when the base potential VBE is increased, a parasitic barrier against electrons is formed in the vicinity of the base-collector junction. FIGS. 14 and 15 also illustrate that when the VBE increases to 0.8V or higher, a barrier (denoted by A) is formed in the conduction band. This forms a depressed region (denoted by B) in the band, thereby increasing the electron concentration in this region, so that recombination with holes tends to occur. As a result, the base current increases, thereby rapidly reducing the hFE, so that the hFE linearity degrades. Note that in FIGS. 14 and 15, a depth of about 0.07 μm corresponds to the vicinity of a base-collector junction surface.

Here, the bipolar transistor 100 of the present embodiment includes the band modulation layer 30, so that the energy in this region (the part denoted by C in FIG. 14) is reduced. Due to such energy reduction, in comparison to the comparative example of FIG. 15, the barrier (the part denoted by A) in the vicinity of the base-collector junction is lowered in the case of the bipolar transistor of FIG. 14. Thus, the increase of the electron concentration in the depressed region (the part denoted by B) is alleviated, thereby rendering the hFE linearity less susceptible to degradation. That is, the hFE linearity can be improved by providing the band modulation layer 30.

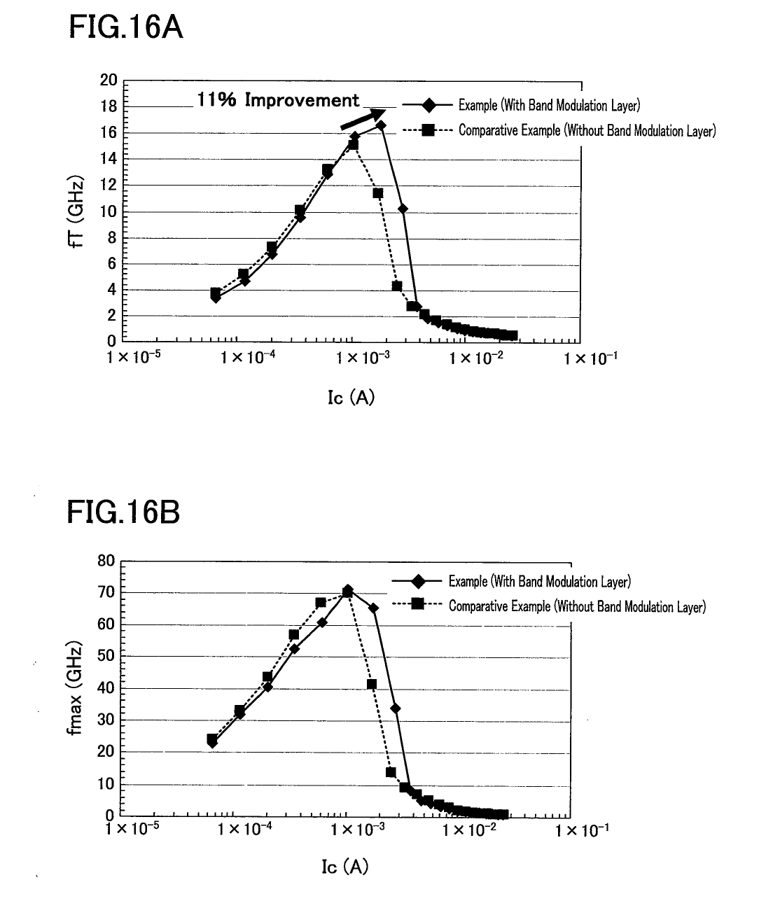

FIGS. 16A and B illustrate the high-frequency performance (cutoff frequency fT and maximum operating frequency fmax) of the example bipolar transistor 100 and the bipolar transistor of the comparative example. These diagrams reveal that due to the improvement in hFE linearity achieved in the example, the peak fT is improved by about 11% while the fmax performance is not degraded.

As described above, the example bipolar transistor 100 of the present embodiment can conduct more current than the comparative example provided that the example bipolar transistor 100 has the same area as that of the comparative example. Thus, the example bipolar transistor 100 is advantageous to application to amplifiers for transmission. Moreover, provided that the amount of current is the same in the example bipolar transistor 100 and the comparative example, the size of the example bipolar transistor 100 can be reduced, so that the parasitic capacitance is reduced, thereby improving the performance.

Note that in the case of the present embodiment, the profile from directly under the base to the sub-collector is generated by one-time phosphorus implantation. However, to optimize the concentration profile, multiple-step implantation may be performed.

Moreover, the thickness of the Si buffer layer 51 directly above the collector may be but not limited to 60 nm. The Si buffer layer 51 needs to have a thickness which compensates defects on the corrector in order to provide a high-quality film, and in which growth nuclei are formed to allow film formation even on the oxide film. Although a specific value depends on the growth condition of SiGe, the Si buffer layer 51 is preferably has a thickness of, for example, 5 nm or larger, and more preferably has a thickness of 10 nm or larger.

Moreover, when the thickness of the Si buffer layer 51 is too large, the thickness of the Si buffer layer 51 may affect the transistor performance. This is because the larger the thickness of the Si buffer layer 51 is, the longer transit time the electrons need, so that the cutoff frequency fT is degraded. For this reason, the thickness of the Si buffer layer 51 is preferably, for example, 100 μm or less, and more preferably 80 μm or less. When the Si buffer layer 51 has such a thickness, the degradation in fT is small.

Moreover, in the present embodiment, the base layer (SiGe layered film 31a) may be but not limited to the SiGe mixed-crystal film. According to required performance, for example, a SiGeC mixed-crystal film may be used.

Moreover, in the above description, in order to form the band modulation layer 30, phosphorus is used as an impurity in consideration of reducing damages in crystals. However, as long as the required performance is not affected, arsenic or antimony may be used as an alternative to phosphorus. In this case, a shallower (narrower) N-type impurity layer can be formed in comparison to the case of using phosphorus.

Moreover, in the case of the bipolar transistor 100, the SiGe-HBT is only formed, but it is easily possible to provide a BiCMOS process by simultaneously forming a CMOS.

When the above bipolar transistor is a bipolar transistor including an epitaxial base layer, in particular, a heterojunction bipolar transistor, the above bipolar transistor provides a high-performance, high-voltage transistor, and is useful in applications such as an amplifier for transmission, and the like.

1. A bipolar transistor comprising:
a heterojunction intrinsic base layer epitaxially formed on a collector layer, wherein
the intrinsic base layer is disposed on the collector layer surrounded by an isolation layer,
an N-type impurity layer is formed in a surface portion of the collector layer, where an impurity concentration of the N-type impurity layer is higher than an impurity concentration of the collector layer under the N-type impurity layer, and
between the N-type impurity layer and the intrinsic base layer, an epitaxially grown layer is formed, where the epitaxially grown layer is lower in impurity concentration than the N-type impurity layer and the intrinsic base layer.

2. The bipolar transistor of claim 1, wherein
an emitter layer is provided on the intrinsic base layer, and
an emitter electrode made of polysilicon is provided on the emitter layer.

3. The bipolar transistor of claim 1, wherein the intrinsic base layer is made of a mixed-crystal material containing at least Si and Ge.

4. The bipolar transistor of claim 1, wherein the epitaxially grown layer has a thickness of greater than or equal to 5 nm and less than or equal to 100 nm.

5. The bipolar transistor of claim 1, wherein the epitaxially grown layer has a thickness of greater than or equal to 10 nm and less than or equal to 80 nm.

6. The bipolar transistor of claim 1, wherein the epitaxially grown layer is an undoped silicon layer.

7. The bipolar transistor of claim 1, wherein the N-type impurity layer is formed by ion implantation.

8. The bipolar transistor of claim 1, wherein the intrinsic base layer is made of a mixed-crystal material containing at least Si, Ge, and C.

9. A method for fabricating a bipolar transistor comprising:
(a) forming a single-crystal silicon layer on a collector layer provided on a silicon substrate;
(b) forming in the single-crystal silicon layer, a collector lead layer and an N-type impurity layer which are isolated from each other by an isolation layer, where the N-type impurity layer is higher in impurity concentration than the collector lead layer;
(c) forming an epitaxially grown layer on the N-type impurity layer, and forming an intrinsic base layer on the epitaxially grown layer;
(d) forming an emitter electrode over the intrinsic base layer with an oxide film interposed therebetween; and
(e) forming an emitter layer in an upper portion of the intrinsic base layer by dispersing impurities from the emitter electrode to the intrinsic base layer by a thermal treatment.

10. The method of claim 9, wherein a layered structure including the epitaxially grown layer and the intrinsic base layer formed at (c) includes a layer made of Si, a layer made of a mixed-crystal material of Si and Ge, and a layer made of a mixed-crystal material of Si and Ge and having a concentration gradient.
